(19) United States
(12) Patent Application Publication
(10) Pub. No.: US 2010/0207184 A1
(43) Pub. Date: Aug. 19, 2010

(54) Semiconductor devices and methods of forming the same

(75) Inventors: Kihyun Kim, Hwaseong-si (KR); Hansoo Kim, Suwon-si (KR); Wonseok Cho, Suwon-si (KR); Jinho Kim, Hwaseong-si (KR); Jaehoon Jang, Seongnam-si (KR); Byoungkeun Son, Suwon-si (KR)

Correspondence Address: MILLS & ONELLO LLP, ELEVEN BEACON STREET, SUITE 605, BOSTON, MA, 02108, US

(73) Assignee: Samsung Electronics Co., Ltd., Suwon-si (KR)

(21) Appl. No.: 12/658,154

(22) Filed: Feb. 3, 2010

(30) Foreign Application Priority Data
Feb. 16, 2009 (KR) 10-2009-0012497

(51) Int. Cl. H01L 29/78

(52) U.S. Cl. 257/314; 257/E29.255

(57) ABSTRACT

A semiconductor device includes insulating patterns and gate patterns alternately stacked on a substrate; an active pattern on the substrate, which extends upward along sidewalls of the insulating patterns and the gate patterns; data storage patterns interposed between the gate patterns and the active pattern; and a source/drain region disposed in the active pattern between a pair of gate patterns adjacent to each other.

### CROSS-REFERENCE TO RELATED APPLICATIONS

This U.S. non-provisional patent application claims priority under 35 U.S.C. §119 to Korean Patent Application 10-2009-0012497, filed on Feb. 16, 2009, the contents of which are herein incorporated by reference in their entirety.

### BACKGROUND

1. Field

The present inventive concept relates to a semiconductor device and a method of forming the same, and more particularly, to a nonvolatile semiconductor device and a method of forming the same.

2. Description of the Related Art

Due to a tendency toward miniaturization and multi-function of electronic equipment, high integration of semiconductor devices built in the electronic equipment is necessary. However, in order to achieve the high integration of the semiconductor devices, components of the semiconductor devices must to be formed to be finer or smaller while maintaining characteristics of each component. High-priced equipment is required in order to form the finer components. However, there is a limit as to how fine the high-priced equipment can make the components.

### SUMMARY

The present inventive concept provides a semiconductor device and a method of forming the same.

According to one aspect, a semiconductor device includes insulating patterns and gate patterns alternately stacked on a substrate, an active pattern on the substrate which extends upward along sidewalls of the insulating patterns and the gate patterns, data storage patterns interposed between the gate patterns and the active pattern, and a source/drain region disposed in the active pattern between a pair of gate patterns adjacent to each other.

In one exemplary embodiment, a dopant concentration in the source/drain region may different from a dopant concentration in the active pattern.

In one exemplary embodiment, sidewalls of the insulating patterns define an undercut region by being recessed laterally relative to sidewalls of the gate patterns. A semiconductor pattern may be disposed in the undercut region, and the source/drain region may extend in the semiconductor pattern in the undercut region.

In one exemplary embodiment, the data storage patterns may extend to be interposed between the source/drain region in the undercut region and the gate pattern.

In one exemplary embodiment, the data storage patterns may include a tunnel barrier adjacent to the active pattern, a blocking insulating pattern adjacent to the gate pattern, and a charge storage pattern interposed between the tunnel barrier and the blocking insulating pattern.

In one exemplary embodiment, a plurality of source/drain regions may be disposed in the active pattern and vertically spaced apart from one another.

In one exemplary embodiment, the semiconductor device may further include a base source region disposed between a lowermost gate pattern and the substrate; and a string drain region disposed on an uppermost gate pattern.

According to another aspect, a method of forming a semiconductor device includes stacking alternately first substance layers and second substance layers on a substrate, forming an opening that penetrates the first and second substance layers, defining an undercut region by recessing sidewalls of the first substance layers exposed by the opening, forming a semiconductor pattern including dopants in the undercut region, forming an active pattern extending upward along sidewalls of the first and second substance layers in the opening, and forming a source/drain region by moving the dopants in the semiconductor pattern into the active pattern.

In one exemplary embodiment, the method may further include forming a trench by patterning successively the first and second substance layers next to the opening, forming empty regions exposing a sidewall of the active pattern by removing the second substance layers exposed by the trench, forming a data storage pattern on the sidewall of the exposed active pattern, and forming gate patterns each filling the empty regions.

In one exemplary embodiment, the method may further include forming a data storage layer on an inner wall of the undercut region and the sidewalls of the second substance layers exposed by the opening before the semiconductor pattern is formed. In this embodiment, the second substance layers may include a conductive substance.

### BRIEF DESCRIPTION OF THE DRAWINGS

The foregoing and other features and advantages of the inventive concept will be apparent from the more particular description of preferred aspects of the inventive concept, as illustrated in the accompanying drawings in which like reference characters refer to the same parts throughout the different views. The drawings are not necessarily to scale, emphasis instead being placed upon illustrating the principles of the inventive concept. In the drawings, the thickness of layers and regions are exaggerated for clarity. In the drawings:

FIG. 1 is a plan view illustrating a semiconductor device according to an exemplary embodiment of the inventive concept;

FIG. 2A is a cross-sectional view taken along a line I-I′ of FIG. 1, and FIG. 2B is an enlarged view of region “A” of FIG. 2A;

FIGS. 3A through 3J are views illustrating a method of forming the semiconductor device of FIGS. 1 and 2 according to an exemplary embodiment of the inventive concept;

FIG. 4 is a plan view illustrating a semiconductor device according to another exemplary embodiment of the inventive concept;

FIG. 5A is a cross-sectional view taken along a line II-II′ of FIG. 4,

FIG. 5B is a cross-sectional view taken along a line III-III′ of FIG. 4, and

FIG. 5C is an enlarged view of region “B” of FIG. 5B;

FIGS. 6A through 6E are views illustrating a method of forming the semiconductor device of FIGS. 4, 5A and 5B according to an exemplary embodiment of the inventive concept; and

FIGS. 7 and 8 are views illustrating applications of the semiconductor device according to the exemplary embodiments of the inventive concept.

### DETAILED DESCRIPTION OF EMBODIMENTS

A semiconductor device and a method of forming the semiconductor device according to exemplary embodiments of the inventive concept will be described below with reference to the accompanying drawings. The exemplary embodiments of the inventive concept may, however, be embodied in many different forms and should not be construed as being limited to the embodiments set forth herein. Rather, these embodiments are provided so that this disclosure will be thorough and complete and will fully convey the scope of the inventive concept to those skilled in the art.

The terminology used herein is for the purpose of describing various embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the terms “and/or” is intended to include any and all combinations of one or more of the associated listed items. It will be understood that when an element or layer is referred to as being “on another element or layer, it may be directly on the other element or layer or intervening elements or layers may be present. It will be understood that, although the terms first, second, third, etc. may be used herein to clearly describe various elements, components, regions, layers, and/or sections, these elements, components, regions, layers, and/or sections should not be limited by these terms. In drawings, the thickness and relative thickness of layers and regions is exaggerated to clearly describe the exemplary embodiments of the present inventive concept.

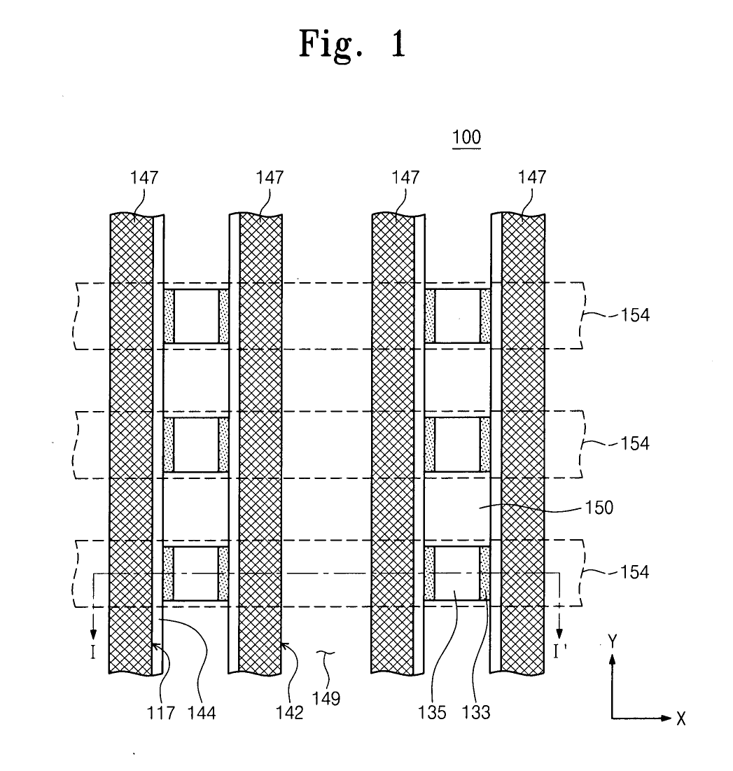

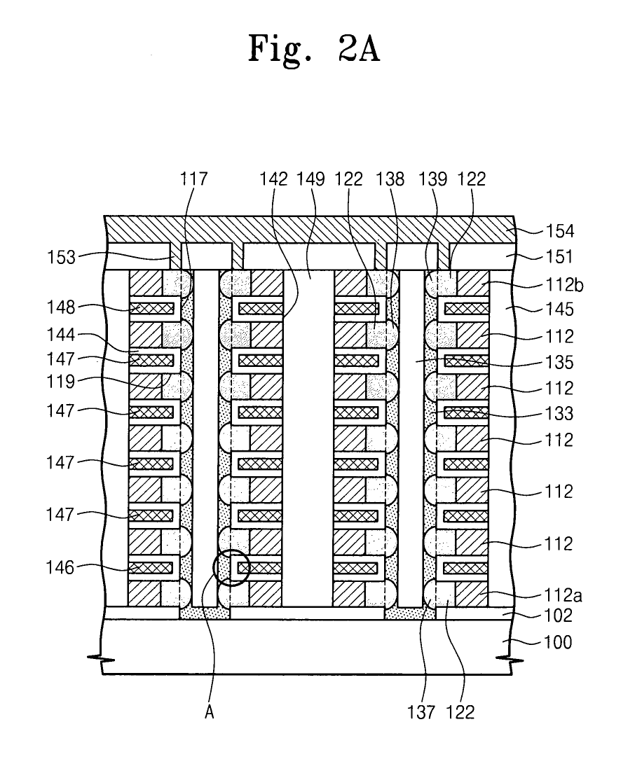

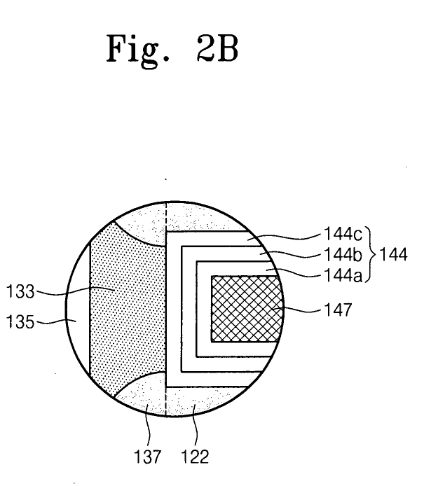

A semiconductor device according to an exemplary embodiment of the inventive concept will be described with reference to FIGS. 12A and 2B. FIG. 1 is a plan view of a semiconductor device according to an exemplary embodiment of the inventive concept, FIG. 2A is a cross-sectional view taken along a line I-I′ of FIG. 1, and FIG. 2B is an enlarged view of region “A” of FIG. 2A.

Referring to FIG. 1 and FIG. 2A, a substrate 100 including cell regions is provided. The substrate 100 may be a semiconductor-based substrate. The substrate 100 may include well regions doped with a first conductive type dopant. A common source region 102 may be disposed in the cell regions. The common source region 102 may be disposed in an upper portion of the substrate 100. The common source region 102 may be doped with a second conductive type dopant.

As illustrated in FIG. 2A, a plurality of cell gate patterns 147 may be stacked on the substrate 100. The cell gate patterns 147 vertically stacked on the substrate 100 may form one group. Intergate insulating patterns 112 may be interposed between the cell gate patterns 147. The cell gate patterns 147 and the intergate insulating patterns 112 may alternately be stacked on the substrate. The intergate insulating patterns 112 may include a first sidewall that is substantially coplanar with one sidewall of the cell gate pattern 147. A second sidewall of the intergate insulating pattern 112 may be recessed laterally compared to another sidewall of the cell gate pattern 147 to define an undercut region 119. The second sidewall of the intergate insulating pattern 112 may be opposite to the first sidewall of the intergate insulating pattern 112. A semiconductor pattern 122 may be disposed in the undercut region 119.

A lower selection gate pattern 146 may be disposed between the substrate 100 and the lowermost cell gate pattern 147. A base insulating pattern 112a may be interposed between the lower selection gate pattern 146 and the substrate 100. An upper selection-gate pattern 148 may be disposed on the uppermost cell gate pattern 147. An upper insulating pattern 112b may be disposed on the upper selection gate pattern 148.

As illustrated in FIG. 1, a group of the cell gate patterns 147 may extend along a first direction. The upper and lower selection gate patterns 146 and 148 may extend in parallel with the cell gate patterns 147. An opening 117 may be disposed between a pair of cell gate patterns 147. The opening 117 may be a groove form extending along the first direction. The first direction may be a Y-axis direction. A bit line 154 extending along a second direction may be disposed on the substrate 100. The second direction may intersect with the first direction. The second direction may be an X-axis direction.

Referring to FIGS. 1 and 2A, an active pattern 133 may be disposed on the substrate 100 to extend upward along the sidewalls of the plurality of the cell gate patterns 147. One active pattern 133 may extend upward along the sidewalls of one group of cell gate patterns 147. The extending direction of the group of cell gate patterns 147 is vertical to that of the active pattern 133 from the substrate 100. For example, the active pattern 133 may extend in the direction vertical to the first and second direction, that is, the direction substantially vertical to the upper surface of the substrate 100.

The plurality of the active patterns 133 may be disposed in one opening 117. The plurality of the active patterns 133 may be arranged along the first direction in which the opening 117 extends. That is, the active patterns 133 may be arranged in a row within the opening 117 between the two groups of the cell gate patterns 147 facing each other.

In one embodiment of the inventive concept, the active pattern 133 may include a bottom in contact with the substrate 100 and a sidewall extending along the sidewalls of the gate patterns 147. For example, the bottom of the active pattern 133 may be disposed on the substrate 100 in the opening 117. The sidewall of the active pattern 133 extends from the edge of the bottom and may be disposed on the sidewalls of the gate patterns 147. A section of the activative pattern 133 vertical to the upper surface may have a U-type shape. A filling insulating pattern 135 may be interposed between the sidewalls of the active pattern 133.

In another embodiment of the inventive concept, the active pattern 133 may not include the bottom. For example, the active pattern 133 may include a first sidewall and a second sidewall, which are separated from each other. The first sidewall and the second sidewall may be a spacer type to cover a portion of the sidewalls of the semiconductor pattern 122 and the gate patterns 146, 147, and 148. The filling insulating pattern 135 may further be interposed between the first sidewall and the second sidewall.

In still another embodiment of the inventive concept, the active pattern 133 may have a filled-column type shape. For example, the active pattern 133 may be a filled-circle column or a filled-polygon column. In this case, the filling insulating pattern 135 between the sidewalls of the active pattern 133 may be omitted

One cell string includes the active pattern 133, the group of the cell gate patterns 147 stacked along one sidewall of the active pattern 133, and the upper and lower selection gate patterns 146 and 148.

The active pattern 133 may include a semiconductor substance. For example, the active pattern 133 may include a single crystalline or poly-crystalline semiconductor. The active pattern 133 may be doped with the first conductive type dopants. Alternatively, the active pattern 133 may not include dopants.

A source/drain region 138 may be disposed in the active pattern 133 between the cell gate patterns 147. The source/drain region 138 may be doped with the second conductive type dopants. That is, the source/drain region 138 may be doped with the same dopants as the common source region 102. The source/drain region 138 may be doped with dopants which are different from those of the well region. The plurality of source/drain regions 138 are disposed within one active pattern 133. The source/drain regions 138 in one sidewall of the active pattern 133 may be symmetrical with the source/drain regions 138 around the filling insulating pattern 135 in another sidewall of the active pattern 133. In this embodiment, one source/drain region 138 disposed in one sidewall of the active pattern 133 and another source/drain region 138 disposed in another sidewall of the active pattern 133 are spaced apart from each other.

The source/drain regions 138 between the cell gate patterns 147 in one group may be vertically spaced apart from each other in the active pattern 133. The source/drain regions 138 may be located on the sidewall of the intergate insulating patterns 112, respectively. The active pattern 133 between the source/drain regions 138 adjacent to each other may be a channel region.

The source/drain region 138 may extend in the semiconductor pattern 122 of the undercut region 119. In this embodiment, the source/drain region 138 may come in contact with the intergate insulating pattern 112.

A concentration of dopant in the source/drain regions 138 may differ from a concentration of dopant in the active pattern 133 around the source/drain regions 138. In one exemplary embodiment on the inventive concept, the active pattern 133 and the source/drain regions 138 may be doped with conductive type dopants which are different from each other. That is, the source/drain regions 138 may be doped with a dopant which is different from that of the active pattern 133 around the source/drain regions 138. For example, the active pattern 133 may include p-type dopants, and the source/drain regions 138 may include n-type dopants.

In another exemplary embodiment of the inventive concept, the active pattern 133 may not include dopants in a region other than the source/drain regions 138. In this embodiment, the concentration of the electrons and holes in the source/drain regions 138 is higher than the concentration of the electrons and holes in the active pattern 133.

A base source region 137 may be disposed between the lower selection gate pattern 146 and the substrate 100. The base source region 137 may be disposed in the lower portion of the active pattern 133. The base source region 137 may be electrically connected to a common source region 102 of the substrate 100. In an exemplary embodiment of the inventive concept, a conductive type dopant included in the common source region 102 may be the same as a conductive type dopant included in the base source region 137. The base source region 137 may serve as a source region of a lower selection transistor including the lower selection gate pattern 146.

In an exemplary embodiment of the inventive concept, a plurality of the base source regions 137 may be disposed to be symmetric with respect to the sidewalls of the active pattern 133. In another exemplary embodiment of the inventive concept, one base source region 137 may be disposed in one active pattern 133.

A string drain region 139 may be disposed on the upper selection gate pattern 148. The string drain region 139 may have a dopant concentration which is different from that of another region in the active pattern 133. The string drain region 139 may be disposed in the upper portion of the active pattern 133. The string drain region 139 may extend next to the inside of a semiconductor pattern 122 in the undercut region 119. The string drain region 139 may be a drain region of an upper selection transistor including the upper selection gate pattern 148. In the embodiment of the inventive concept, two string drain regions 139 may be disposed to be symmetric in both sidewalls of the active pattern 133.

The string drain regions 139 may be electrically connected to the bit line 154. A bit line contact 153 may be interposed between the bit line 154 and the string drain region 139. One bit line contact 153 may be contacted to one string drain region 139 on one sidewall of the upper insulating pattern 112b. Alternatively, the one bit line contact 153 may be contacted to a pair of string drain regions 139 on opposing sidewalls of the upper insulating pattern 112b. The bit line contact 153 may be surrounded by an inter-layer insulating layer 151. The bit line 154 extends in a direction perpendicular to a direction in which the cell gate patterns 147 extend.

When base source regions 137, source/drain regions 138 and string drain regions 139 doped with dopant are disposed between the lower selection gate patterns 146, cell gate patterns 147 and upper selection gate patterns 148, charges may be easily supplied to the inside of the active pattern 133. Accordingly, it is not essential to supply a negative voltage for turning off channels or to restrict a distance between the gate patterns for preventing fringing field and disturbance.

When no source/drain regions are disposed between gate patterns, it may be difficult to operate a cell string including the gate patterns. Specifically, in order to operate the cell string in which no dopant regions separated from each other between the gate patterns are disposed, a depletion mode or a fringing field may be used. First, when the depletion mode is used, a negative voltage is applied to a selection transistor of the cell string in order to turn off the active pattern. In order to supply the negative voltage, an additional power supplying unit is necessary. Therefore, a peripheral circuit may become complicated, which is disadvantageous to high integration.

Second, when the fringing field is used, a distance between the gate patterns has to be sufficiently narrow in order to overlap with the electric fields generated in the gate patterns. When the distance between the gate patterns is not sufficiently narrow, a sufficient ON current may not be supplied in a wiring operation of cells. For this reason, since the writing and/or reading operation may not be properly executed, reliability of a semiconductor device may deteriorate. Even when the distance between the gate patterns is sufficiently narrow, disturbance between the gate patterns that are vertically adjacent to each other may be increased.

According to the exemplary embodiments of the inventive concept, however, when the source/drain regions 138 are disposed between the cell gate patterns 147, it is easy to supply charges to the inside of the active pattern 133. That is, it is not essential to supply the negative voltage for turning off the channels or to restrict the distance between the gate patterns in order to prevent the occurrence of a fringing field and a disturbance. Accordingly, it is possible to provide a semiconductor device with high integration and improved reliability.

Data storage patterns 144 are disposed on the sidewalls of the gate patterns 146, 147, and 148. The data storage patterns 144 cover the sidewall of an opening 117. The data storage patterns 144 are disposed between the gate patterns 146, 147, and 148 and the active pattern 133. In an embodiment of the inventive concept, the data storage patterns 144 may extend on the upper and lower surfaces of the gate patterns 146, 147, and 148. The data storage patterns 144 may cover at least one of the upper and lower surfaces of the gate patterns 146, 147, and 148. The data storage patterns 144 extend to be disposed between the semiconductor patterns 122 and the gate patterns 146, 147, and 148.

The data storage patterns 144 may include a plurality of layers. Referring to FIG. 2B, the data storage patterns 144 may include a tunnel barrier 144c adjacent to the active pattern 133, a blocking insulating pattern 144a adjacent to the gate patterns 146, 147 and 148, and a charge storage pattern 144b interposed between the tunnel barrier and the blocking insulating pattern. The charge storage pattern includes at least one selected from a group comprising a semiconductor, a nitride, an oxynitride, a metallic oxide, a quantum dot, and a metal. The quantum dot is formed of, for example, metal, silicon, germanium, or silicon-germanium.

A device isolation pattern 149 extending from the substrate 100 to the upper side of the semiconductor device is disposed along the sidewalls of the cell gate patterns 147, lower selection gate patterns 146 and upper selection gate patterns 148. The device separation pattern 149 fills trenches 142 defined by the sidewalls of the cell gate patterns 147, lower selection gate patterns 146, upper selection gate patterns 148 and the common source region 102. The trench 142 may be formed in the shape of a groove extending in the first direction.

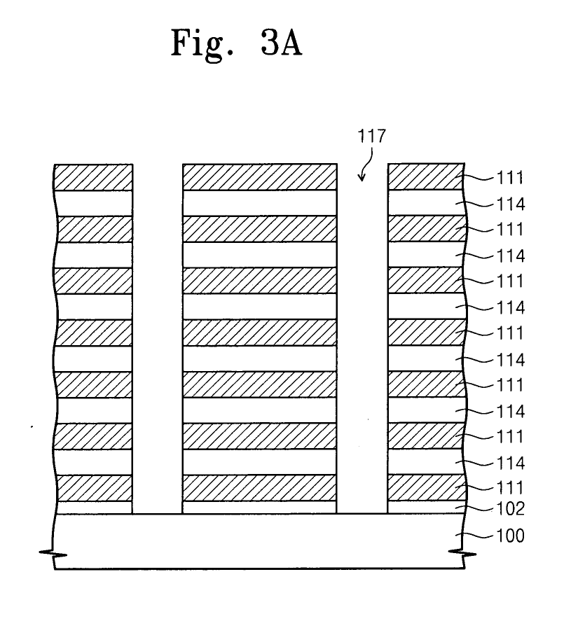

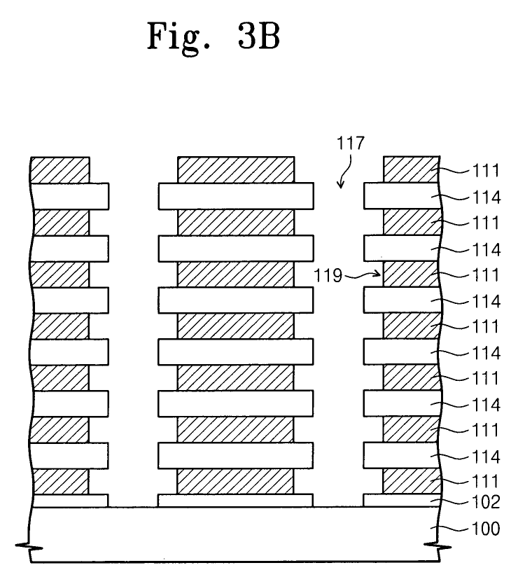

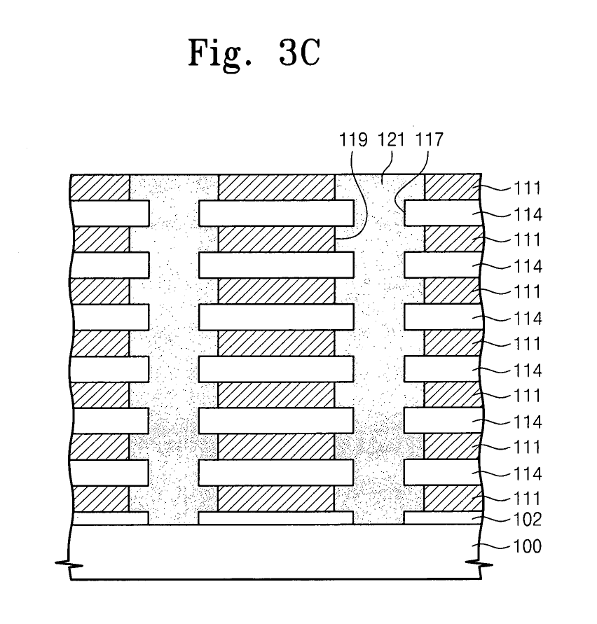

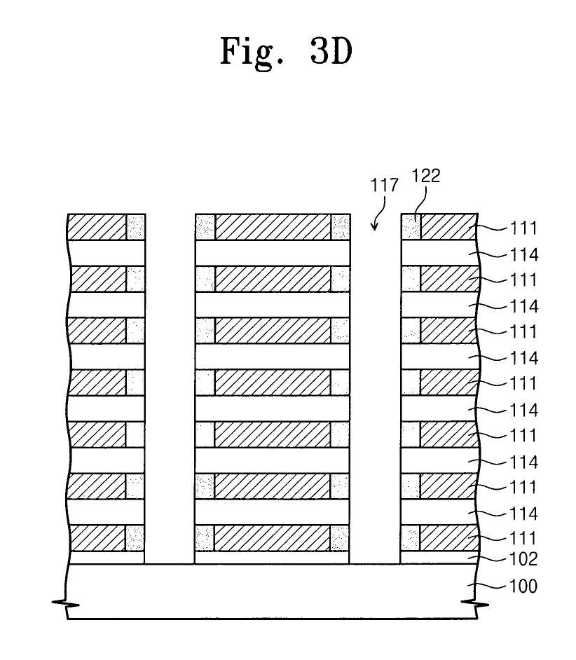

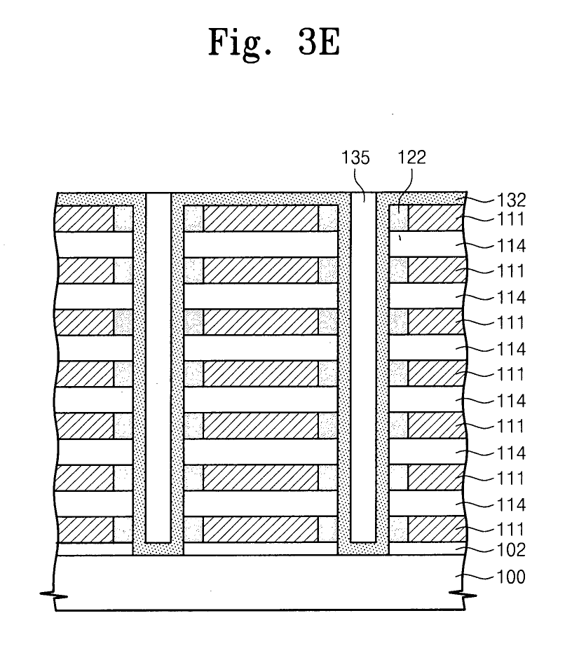

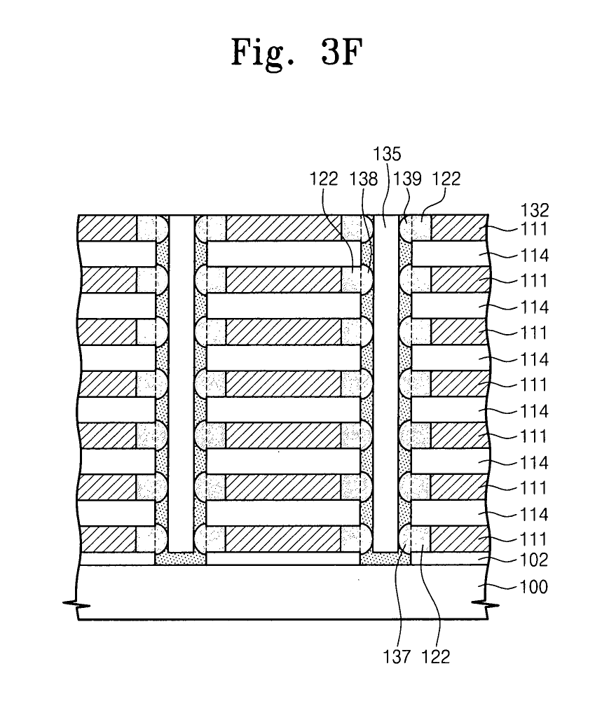

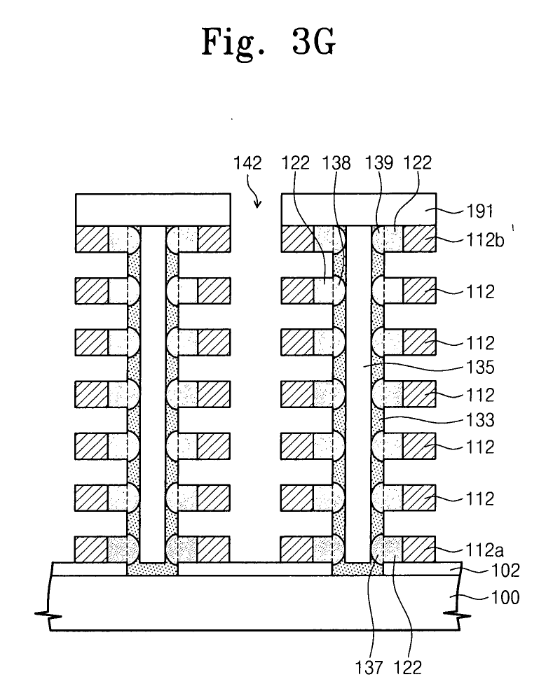

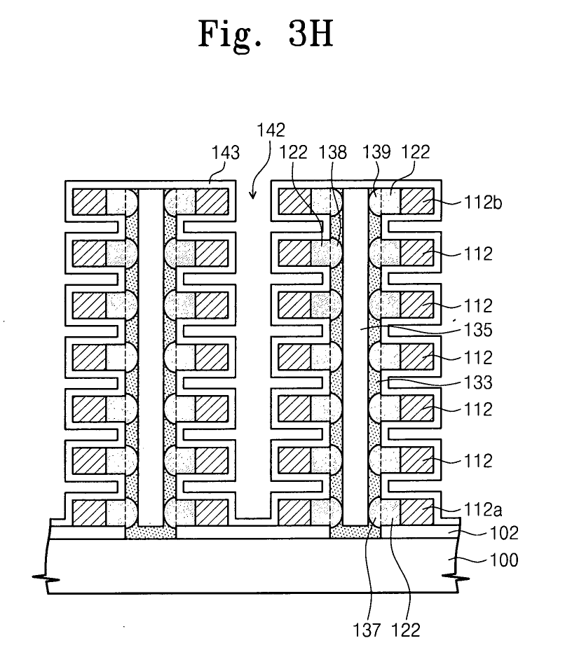

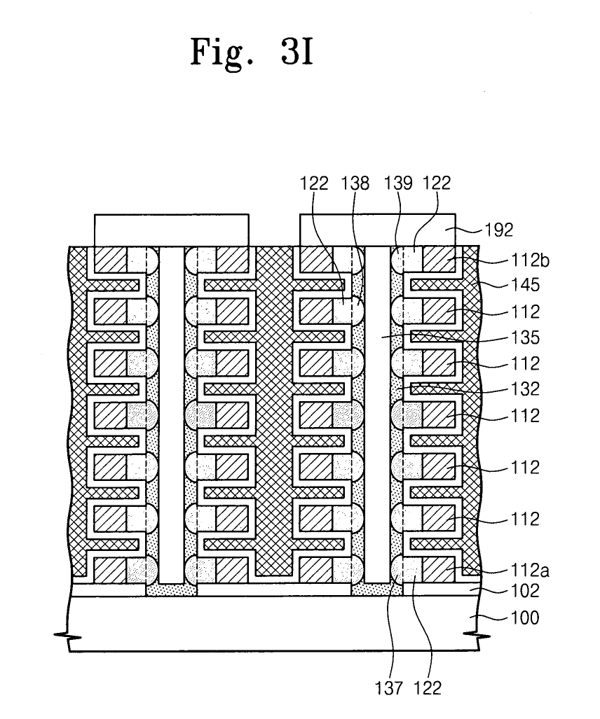

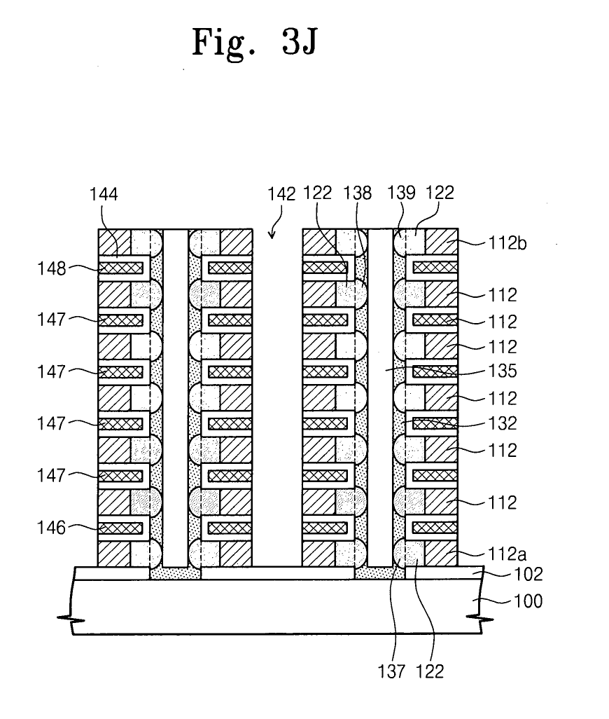

A method of forming the semiconductor device of FIGS. 1 and 2 according to an exemplary embodiment of the inventive concept will be described with reference to FIGS. 1 and, 2A, 2B and FIGS. 3A through 3J. FIGS. 3A through 3J are sectional views illustrating the semiconductor device taken along the line I-I′ of FIG. 1. Some of the description made with reference to FIGS. 1 and 2A may be omitted.

Referring to FIG. 3A, the substrate 100 including a well region is prepared. The substrate 100 may be, for example, a semiconductor-based semiconductor substrate. The well region is formed by injecting dopant into the substrate 100. The dopant included in the well region may be a first conductive type of dopant. The common source region 102 is formed in the well region. The common source region 102 is formed by injecting a second conductive type of dopant into the well region.

First substance layers 111 and second substance layers 114 are alternately stacked on the substrate 100. The first substance layers 111 may include, for example, an insulating substance. For example, the first substance layers 111 may include a silicon oxide. The second substance layers 114 may include, for example, a substance having an etching selection ratio with respect to the first substance layers 111. For example, the second substance layers 114 may include a silicon nitride.

The first substance layers 111 and the second substance layers 114 are patterned so as to form the openings 117 on the substrate 100. The openings 117 include the bottom defined by the upper surface of the substrate 100 and the sidewall defined by the sidewalls of the first substance layers 111 and the second substance layers 114. The openings 117 have the shape of a groove extending in the first direction of the substrate 100. Upon forming the openings 117, a part of the common source region 102 is removed, and the well region of the substrate 100 is exposed.

Referring to FIG. 3B, the undercut regions 119 are formed on the sidewalls of the openings 117 by recessing the first substance layers 111. The undercut regions 119 have side surfaces defined by the recessed sidewalls of the first substance layers 111. The first substance layers 111 may be recessed, for example, by isotropic etching.

Referring to FIG. 3C, a semiconductor layer 121 may be formed in the opening 117. The undercut regions 119 are filled with the semiconductor layer 121. The semiconductor layer 121 may include a semiconductor substance. For example, the semiconductor layer 121 may include a single-crystalline semiconductor substance, a poly-crystalline semiconductor substance, or an amorphous semiconductor substance. The semiconductor layer 121 may be doped with dopants. The dopants may be a first conductive type or a second conductive type. The semiconductor layer 121 may be formed by a deposition such as a chemical vapor deposition, or an epitaxial growth. The upper surface of the semiconductor layer 121 may be planarized.

Referring to FIG. 3D, the semiconductor layer 121 is etched to form the semiconductor patterns 122. The semiconductor patterns 122 are the semiconductor layers 121 remaining in the undercut regions 119 after the etching process. The semiconductor layer 121 may be etched by performing etching on the uppermost first substance layer 111 by using an etching mask. The etching of the semiconductor layer 121 may be performed until the substrate 100 is exposed. The sidewalls of the semiconductor patterns 122 and the sidewalls of the second substance layers 114 may be self-aligned by etching the semiconductor layer 121.

Referring to FIG. 3E, an active layer 132 is formed in the opening 117 in which the semiconductor pattern 122 is formed. The active layer 132 may be formed conformally on the sidewall and the bottom of the opening 117. Alternatively, the active layer 132 may be formed by filling the inside of the opening 117 with the semiconductor substance and then removing a part of the semiconductor substance. The active layer 132 formed on the bottom of the opening 117 may selectively be removed or remain on the bottom portion of the opening 117. Alternatively, the opening 117 may be filled with the active layer 132.

The active layer 132 may include, for example, a single-crystalline semiconductor substance or a poly-crystalline semiconductor substance. In an exemplary embodiment of the inventive concept, the active layer 132 may be doped with dopants. The dopants may be an n-type or a p-type. Alternatively, the active layer 132 is not doped.

A filling insulating layer 135 is formed in the opening 117. The filling insulating layer 135 may fill the opening 117 in which the active layer 132 is formed. When the opening 117 is filled with the active layer 132, the filling insulating layer 135 may be omitted.

Referring to FIG. 3F, the upper surface of the active layer 132 may be planarized. The planarizing of the active layer 132 may be performed until the upper surface of the first substance layer 111 is exposed. Upon planarizing the active layer 132, a portion of the filling insulating layer 135 may be removed.

The source/drain regions 138 may be formed in the active layer 132 by moving the dopants in the semiconductor pattern 122. The base source region 137 and the string drain region 139 are formed in the upper and lower portions of the active layer 132, respectively, by moving the dopants in the uppermost and lowermost semiconductor patterns 122, respectively. The dopants are moved next to the first substance layer 111 in the active layer 132 and some of the dopants may be moved onto the sidewall of the second substance layer 114. The dopants may move in an isotropic manner. In an exemplary embodiment of the inventive concept, the dopants may be moved in by diffusion. The diffusion of the dopants may be performed by an annealing process.

In the method of forming the semiconductor device according to the embodiment, the base source region 137, the source/drain regions 138 and the string drain region 139 may be formed by partially forming the semiconductor pattern 122 with the dopants between the gate patterns 146, 147, and 148, respectively, and then moving the dopants. Accordingly, the base source region 137, the source/drain regions 138 and the string drain region 139 may be formed at the desired region using a simple process.

Referring to FIG. 3G, a first mask pattern 191 is formed on the first substance layer 111. The first mask pattern 191 covers a part of the first substance layer 111 and the active layer 132.

By performing an etching process using the first mask pattern 191 as a mask, the first substance layer 111 and the second substance layer 114 are etched, and the trench 142 is formed. When the first substance layer 111 is etched, a base insulating pattern 112a, an intergate insulating pattern 112, and an upper insulating pattern 112b may be formed. The common source region 102 may be exposed by this etching process. The etching process may be an isotropic etching.

Subsequently, the second substance layer 114 exposed to the trench 142 are removed and empty regions are formed between the insulating patterns 112a, 112, and 112b. The empty regions are spaces between the insulating patterns 112a, 112, and 112b. The trench 142 may expose the sidewall of the active layer 132. The trench 142 may expose a part of the sidewall of the source/drain regions 138. The trench 142 exposes the upper surface, the lower surface, and one sidewall of the intergate insulating patterns 112.

Referring to FIG. 3H, the first mask pattern 191 is removed and a data storage layer 143 is formed in the trench 142. The data storage layer 143 may be conformally formed on the upper surface, the lower surface, and one sidewall of the insulating patterns 112a, 112 and 112b, the exposed sidewall of the active layer 132, and sidewalls of the base source region 137, the source/drain regions 138 and string drain region 139.

The data storage layer 143 may have a plurality of layers. For example, a tunnel barrier conformally covering the inside of the trench 142 is first formed, and then a charge storing layer and a blocking insulating layer are formed on the tunnel barrier.

Referring to FIG. 3I, a gate layer 145 is formed to fill the trench 142 in which the data storage layer 143 is formed. The empty regions between the insulating patterns 112a, 112, and 112b in the trench 142 are filled with the gate layer 145. The gate layer 145 is adjacent to the data storage layer 143. The gate layer 145 includes at least one of a doped semiconductor substance, a metal, and a conductive substance including a metallic compound.

A second mask pattern 192 is formed on the intergate insulating patterns 112. The sidewall of the second mask pattern 192 may be aligned with the sidewalls of the insulating patterns 112a, 112 and 112b.

Referring to FIG. 3J, an etching process is performed using the second mask pattern 192 as an etching mask. The gate layer 145 is etched to form a lowermost lower selection gate pattern 146, an uppermost upper selection gate pattern 148, and cell gate patterns 147 between the lowermost lower selection gate pattern 146 and the uppermost upper selection gate pattern 148. In the etching process, a portion of the data storage layer 143 is etched to form the data storage pattern 144. Specifically, the data storage layer 143 formed on a sidewall that is not adjacent to the source/drain regions 138 of the intergate insulating patterns 112 may be removed. One data storage pattern 144 may be adjacent to two source/drain regions 138. The data storage patterns 144 cover the upper surface, the lower surface, and one sidewall of the cell gate patterns 147, the lower selection gate pattern 146 and upper selection gate pattern 148.

The trench 142 is formed by the etching process. The trench 142 may be a groove extending in the same direction as that of the opening 117. The trench 142 may have the bottom defined by the common source region 102 and a sidewall defined by the insulating patterns 112a, 112, 112b, the sidewall of the data storage pattern 144 and the sidewalls of the gate patterns 146, 147, and 148.

Referring again to FIGS. 1 and 2A, a device isolation layer 149 is formed in the trench 142. Subsequently, the active patterns 133 may be formed by patterning the active layer 132. The plurality of active patterns 133 may be arranged so as to be spaced apart from each other in a direction in which the openings 117 extend. The opening 117 between the active patterns 133 may be filled with an insulating layer 150.

The inter-layer insulating layer 151 may be formed on the structure formed in accordance with the above-described steps. An opening that exposes the string drain region 139 may be formed in the inter-layer insulating layer 151. The bit line contact 153 may be formed in the opening. The bit line contact 153 may be electrically connected to the string drain region 139.

The bit line 154 may be formed on the inter-layer insulating layer 151. The bit line 154 may be line-shaped extending in a second direction.

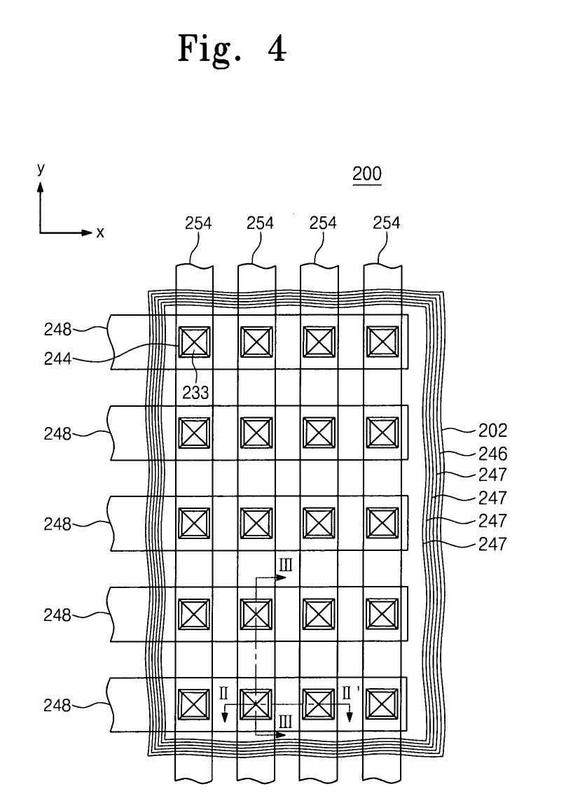

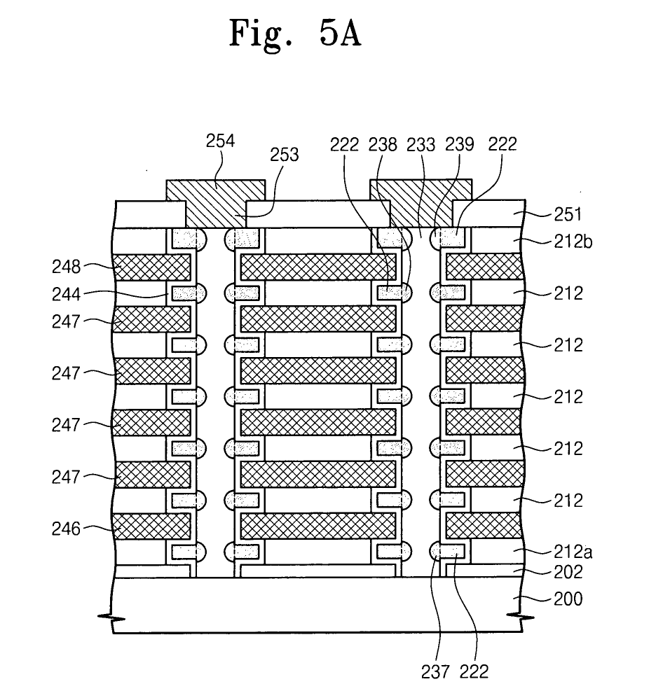

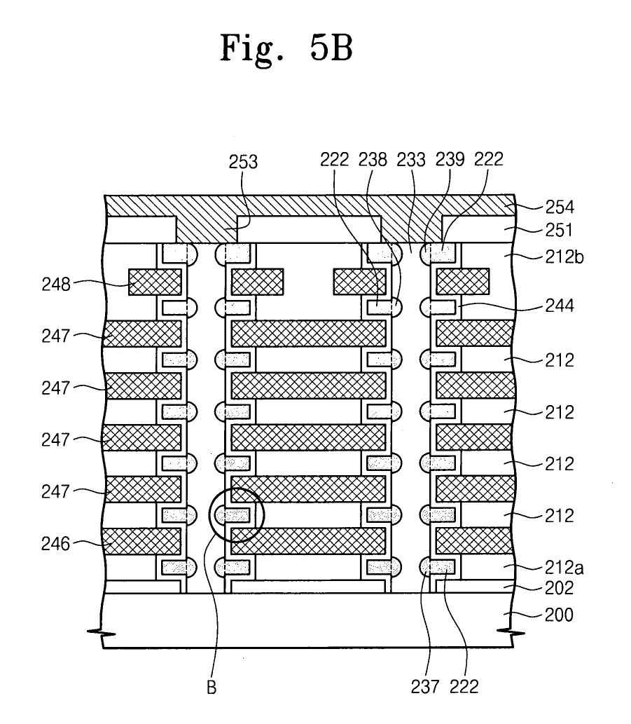

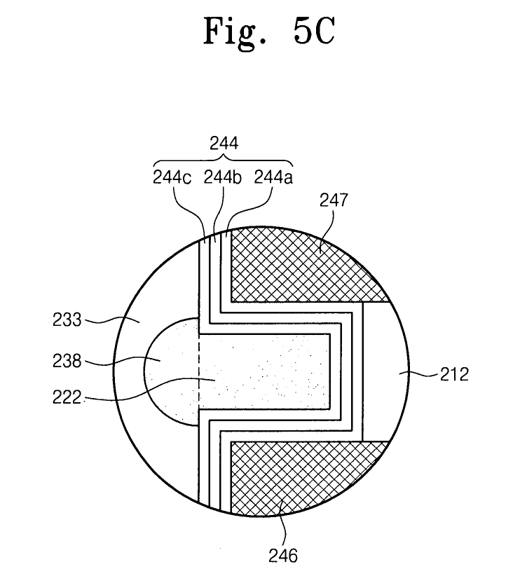

Referring to FIG. 4 and FIGS. 5A, 5B and 5C, a semiconductor device according to another exemplary embodiment of the inventive concept will be described. FIG. 4 is a plan view illustrating a semiconductor device according to another exemplary embodiment of the inventive concept. FIG. 5A is a cross-sectional view illustrating the semiconductor device taken along the line II-II′ of FIG. 4. FIG. 5B is a cross-sectional view illustrating the semiconductor device taken along the line III-III′ of FIG. 4, and FIG. 5C is an enlarged view of region “B” of FIG. 5B.

Referring to FIG. 4 and FIGS. 5A and 5B, a substrate 200 is prepared. The substrate 200 may be, for example, a semiconductor-based semiconductor substrate. The substrate 200 includes a well region. The well region may be doped with the first conductive type dopants. A common source region 202 may be formed in the substrate 200. The common source region 202 may be disposed in the upper portion of the substrate 200. The common source region 202 may be disposed in a plate form on the entire surface of the cell region of the substrate 200.

Cell gate patterns 247 and intergate insulating layers 212 are alternately stacked on the substrate 200. The plurality of cell gate patterns 247 may be stacked on the substrate 200 and the cell gate patterns 247 may be spaced between the intergate insulating layers 212. The cell gate patterns 247 may be disposed in a plate form on the substrate 200.

A lower selection gate pattern 246 may be disposed between the lowermost cell gate patterns 247 and the substrate 200. The lower selection gate patterns 246 may be disposed in a plate form parallel to the cell gate patterns 247 and the substrate 200. A base insulating pattern 212a may be interposed between the lower selection gate pattern 246 and the substrate 200.

An upper selection gate pattern 248 may be disposed above the uppermost cell gate patterns 247. The upper selection gate pattern 248 may be disposed in a line form extending in one direction. For example, the upper selection gate pattern 248 may extend in the X-axis direction. An upper insulating pattern 212b may be disposed on the upper selection gate pattern 248.

The base insulating pattern 212a, the intergate insulating pattern 212, and the upper insulating pattern 212b may be recessed laterally from the sidewalls of the upper gate patterns 246, 247, and 248. The sidewalls of the recessed insulating patterns 212a, 212, and 212b define undercut regions 219. The semiconductor patterns 222 may be disposed in the undercut regions 219. The semiconductor patterns 222 may be disposed next to the recessed insulating patterns 212a, 212, and 212b.

An active pattern 233 may be disposed via the cell gate patterns 247, the upper selection gate pattern 248, the lower selection gate pattern 246, and the insulating patterns 212a, 212, and 212b. The active pattern 233 may be disposed in a column form. Alternatively, the active pattern 233 may be disposed in a plate form with a hollow space therein. In this case, the hollow space in the active pattern 233 is filled with an insulating substance. The active pattern 233 may be surrounded by the cell gate patterns 247. One active pattern 233 may be surrounded by the plurality of semiconductor patterns 222 stacked vertically. Each semiconductor pattern 222 may be surrounded by the intergate insulating pattern 212.

The active pattern 233 may include a semiconductor substance. The active pattern 233 may include, for example, a single-crystalline semiconductor substance or a poly-crystalline semiconductor substance. The active pattern 233 may be doped with dopants. For example, the active pattern 233 may be doped with n-type or p-type conductive dopants. Alternatively, the active pattern 233 is not doped with dopants.

A data storage pattern 244 may be interposed between the active pattern 233 and the cell gate patterns 247, lower selection gate pattern 246 and upper selection gate pattern 248. The data storage pattern 244 may extend along the sidewalls of the cell gate patterns 247, lower selection gate pattern 246, upper selection gate pattern 248 and the insulating patterns 212a, 212 and 212b. The data storage pattern 244 conformally may cover the inner walls of the undercut region 219.

The data storage pattern 244 may include a plurality of layers as depicted in FIG. 5C. For example, the data storage pattern 244 may include a tunnel barrier 244c, adjacent to the active pattern 233, a blocking insulating pattern 244a adjacent to the gate patterns, and a charge storage pattern 244b interposed between the tunnel barrier and the blocking insulating pattern. The charge storage pattern may include at least one of a semiconductor, a nitride, an oxynitride, a metallic oxide, and a quantum dot. The quantum dot is formed of, for example, metal, silicon, germanium, or silicon-germanium.

Source/drain regions 238 are formed in the active pattern 233. The source/drain regions 238 may be disposed in the active pattern 233 between the cell gate patterns 247. The source/drain regions 238 may be disposed next to the intergate insulating patterns 212. In this embodiment, the semiconductor pattern 222 is interposed between the source/drain regions 238 and the intergate insulating patterns 212. The source/drain region 238 may extend into the semiconductor pattern 222.

A plurality of the source/drain regions 238 may be disposed in the active pattern 233. The plurality of source/drain regions 238 may be vertically spaced from each other in the active pattern 233. The source/drain region 238 may have a cross-section of a closed loop shape surrounding the active pattern 233. For example, the source/drain region 238 may be formed in a ring shape surrounding the active pattern 233. At least a part of the source/drain regions 238 may overlap with the active pattern 233. The source/drain regions 238 may extend to the semiconductor pattern 222 surrounding the active pattern 233 so as to exist both inside and outside the active pattern 233.

A base source region 237 is disposed between the lower selection gate pattern 246 and the substrate 200. The base source region 237 may be disposed in the lower portion of the active pattern 233. The base source region 237 may be electrically connected to the common source region 202 of the substrate 200. In an exemplary embodiment of the inventive concept, a conductive type dopant included in the common source region 202 may be the same as a conductive type dopant in the base source region 237. The base source region 237 may serve as a source region of a lower selection transistor including the lower selection gate pattern 246.

A string drain region 239 is disposed on the upper selection gate pattern 248. The string drain region 239 may be a dopant region doped with the same dopants in the active pattern 233. The string drain region 239 may be disposed in the upper portion of the active pattern 233. The string drain region 239 may extend to the inside of the semiconductor pattern in the undercut region 219. The string drain region 239 may be a drain region of an upper selection transistor, which includes the upper selection gate pattern 248.

The source/drain regions 238 may be doped with dopants. The concentration of the dopants in the source/drain regions 238 may be different from the concentration of the dopants in the active pattern 233. In an exemplary embodiment of the inventive concept, when the active pattern 233 includes p-type dopants and the source/drain region 238s include n-type dopants, the concentration of the electrons in the source/drain regions 238 may be higher than the concentration of the holes of the active pattern 233. In another exemplary embodiment of the inventive concept, when both the active pattern 233 and the source/drain regions 238 include p-type dopants, the concentration of the holes in the source/drain regions 238 may be lower than the concentration of the holes in the active pattern 233. In another exemplary embodiment of the inventive concept, when both the active pattern 233 and the source/drain regions 238 include n-type dopants, the concentration of the electrons in the source/drain regions 238 may be higher than the concentration of the electrons of the active pattern 233. Alternatively, the active pattern 233 is not doped with the dopants and only the source/drain regions 238 are doped with the dopants.

As described above, the embodiments of the inventive concept may provide the source/drain regions 238 separated from each other between the cell gate patterns 247. Therefore, it is not essential to provide an additional method for supplying charges into the active pattern 233, for example, a method of supplying a negative voltage in an erasing operation, or a method of restricting a distance between the gate patterns, for example, in the operation of a cell string not including the source/drain regions. Accordingly, the semiconductor device is provided having high integration and improved reliability.

A bit line 254 is formed on the string drain region 239. The bit line 254 may intersect the string drain region 239. The bit line 254 and the string drain region 239 may be connected by a bit line contact 253. The bit line contact 253 is surrounded by an inter-layer insulating pattern 251.

Referring to FIGS. 4, 5A, 5B, 5C and FIGS. 6A to 6E, a method of forming the semiconductor device according another embodiment of the inventive concept will be described. The details described with reference to FIGS. 5A, 5B and 5C may be partially omitted.

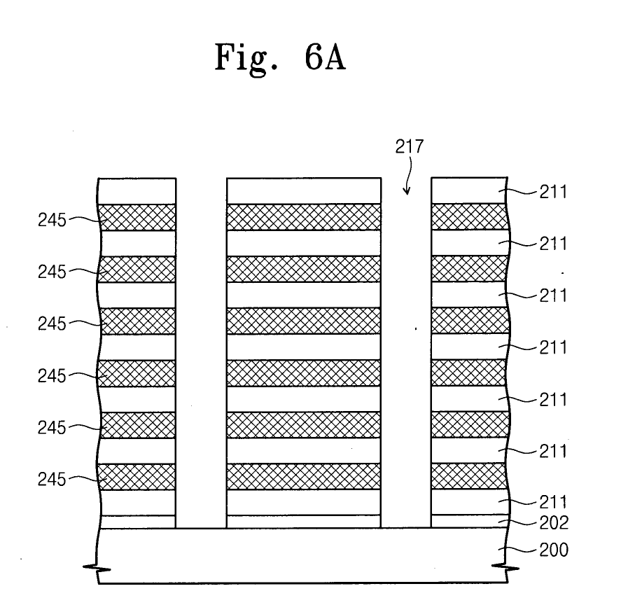

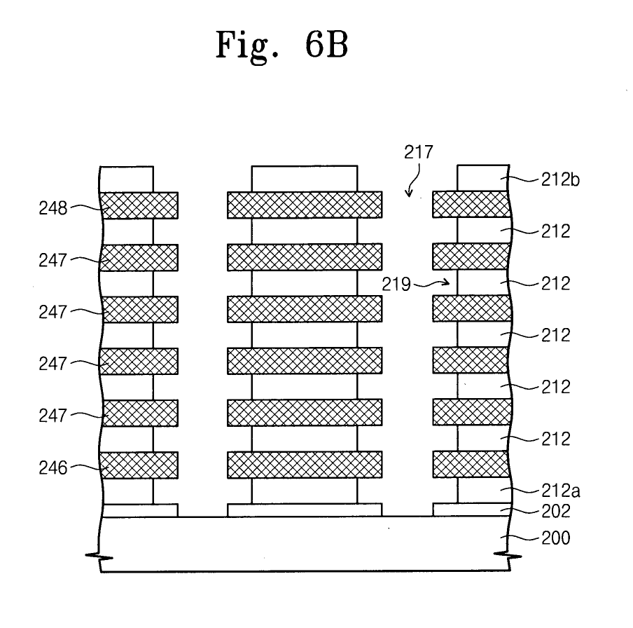

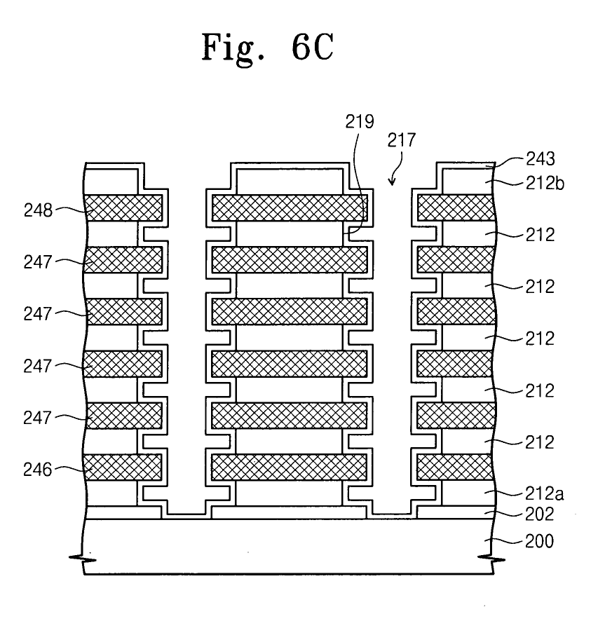

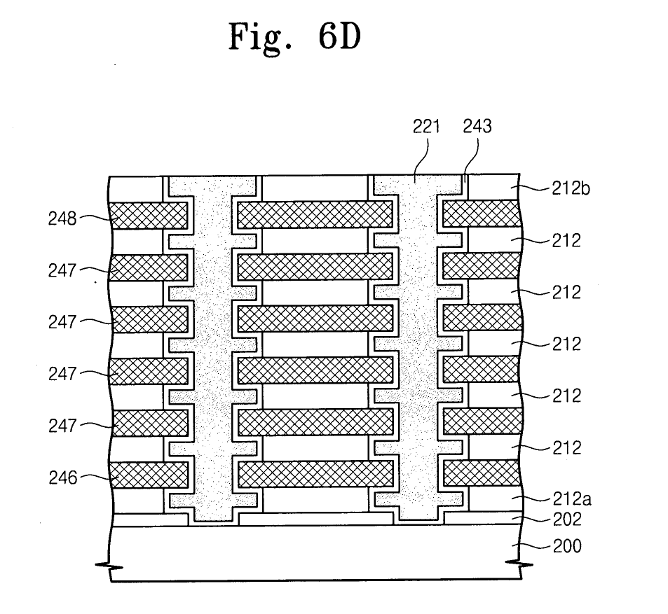

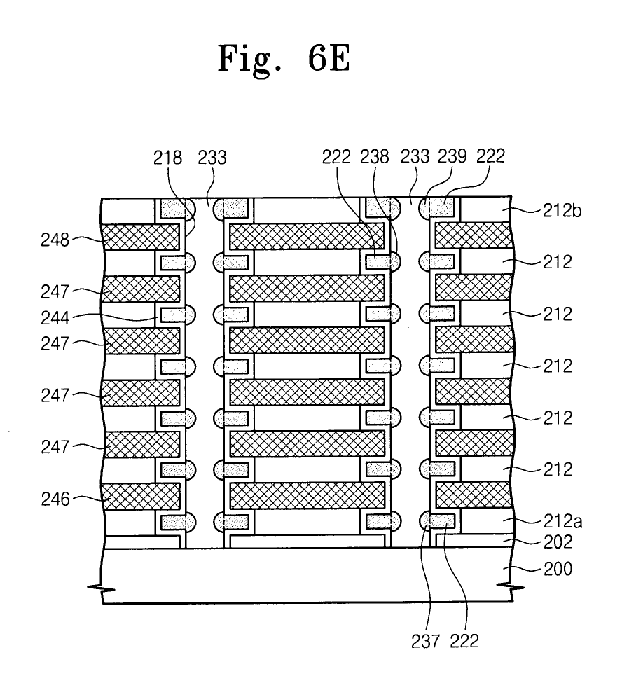

Referring to FIG. 6A, the substrate 200 is prepared. The substrate 200 may include the well region. The well region may be formed by doping the substrate 200 with the first conductive type dopants. A reserve common source region 202 may be formed in the upper portion of the well region of the substrate 200. The reserve common source region 202 may be formed by doping a part of the well region with the second conductive type dopants.

First substance layers 211 and second substance layers 245 may be alternately stacked on the substrate 200. The first substance layers 211 may include an insulating substance. For example, the first substance layers 211 may include an oxide or a nitride. The second substance layers 245 may include, for example, a conductive substance. For example, the second substance layers 245 may include a semiconductor, a doped semiconductor, or a metal.

The first substance layers 211 and the second substance layers 245 may be subjected to an anisotropic etching to form an opening 217. The opening 217 may be a hole type opening. The opening 217 may expose the well regions. The second substance layers 245 may be etched to form the lower selection gate pattern 246, cell gate patterns 247, and an upper selection gate pattern 248.

Referring to FIG. 6B, the base insulating pattern 212a, the intergate insulating pattern 212, and the upper insulating pattern 212b may be formed by recessing the first substance layers 211. The laterally recessed first substance layers 211 define the undercut regions 219. The undercut regions 219 are regions which are formed next to the insulating patterns 212a, 212, and 212b and between the gate patterns 246, 247, and 248.

Referring to FIG. 6C, a data storage layer 243 is formed in the opening 217. The data storage layer 243 is formed to conformally cover the opening 217, the undercut regions 219 and a top surface of the upper insulating pattern 212b. The data storage layer 243 may include a plurality of layers. For example, the data storage layer 243 may include a blocking insulating layer adjacent to the gate patterns 246, 247, and 248, a charge storage layer formed on the blocking insulating layer, and a tunnel barriers formed on the charge storing layer.

Referring to FIG. 6D, a semiconductor layer 221 may be formed in the opening 217 in which the data storage layer 243 is formed. The opening 217 provided with the data storage layer 243 and the undercut regions 219 may be filled with the semiconductor layer 221. The semiconductor layer 243 is doped with dopants. The semiconductor layer 221 may be doped with the first conductive type dopants or the second conductive type dopants. The semiconductor layer 221 may include, for example, a single-crystalline semiconductor substance, a poly-crystalline semiconductor substance, or an amorphous semiconductor substance. The upper surface of the semiconductor layer 221 may be planarized. In the planarizing process, a part of the data storage layer 243 may be removed to expose the upper surface of the upper insulating pattern 212b.

Referring to FIG. 6E, the semiconductor layer 221 is etched to form the semiconductor pattern 222. The semiconductor pattern 222 may be the semiconductor layer 221 filling the undercut regions 219.

The semiconductor layer 221 may be etched by forming a mask on the gate patterns 246, 247, and 248, and the intergate insulating patterns 212a, 212 and 212b and then performing an etching process by using the mask as an etching mask. When the semiconductor layer 221 is etched, the data storage layer 243 is etched to form the data storage pattern 244. Specifically, the data storage layer 243 formed on the well region of the substrate 200 is removed to form the data storage pattern 244.

The active pattern 233 is formed in the opening 217. The opening 217 may be filled with the active pattern 233, and the active pattern 233 may be adjacent to the data storage pattern 244 and the semiconductor pattern 222. Alternatively, the active pattern 233 may be formed in a hollow column shape and be adjacent to the sidewall of the opening 217. In this case, the active pattern 233 may be formed by filling the opening 217 with a semiconductor substance and then performing anisotropic etching on the semiconductor substance. Alternatively, the active pattern 233 may be formed by depositing a layer so as to conformally cover the opening 217. The active pattern 233 may include, for example, a single-crystal semiconductor substance or a poly-crystalline semiconductor substance.

Again referring to FIGS. 5A, 5B, 5C and 6E, the dopants in the semiconductor pattern 222 are moved, so that the source/drain regions 237, 238, and 239 are formed in the active pattern 233. The dopants in the semiconductor pattern 222 are moved to the active pattern 233 by diffusion. In an exemplary embodiment of the inventive concept, an annealing process may be performed to diffuse the dopants.

The source/drain regions 237, 238, and 239 may be formed in the active pattern 233 between the gate patterns 246, 247, and 248. The source/drain regions 237, 238, and 239 may partially extend to the sidewalls of the gate patterns 246, 247, and 248. This may be caused by, for example, isotropic movement of the dopants. Even after the dopants are moved, the dopants may remain in the semiconductor pattern 222.

The source/drain region 237 formed below the lower selection gate pattern 246 extends to the common source region 202. The lowermost source/drain region 237 may be the base source region 237. The source/drain region 239 formed on the upper selection gate pattern 248 may be the string drain region 239.

Referring to FIG. 5B, the upper gate pattern 248 may be patterned additionally. The patterned upper selection gate pattern 248 may be disposed in a line form extending in the first direction. An insulating pattern is formed next to the sidewall of the patterned upper selection gate pattern 248. Alternatively, the upper selection gate pattern 248 may be patterned prior to forming the opening 217.

The bit line 254 may be formed on the string drain region 239. The bit line 254 may extend in the second direction intersecting the first direction. The bit line contact 253 may be formed between the bit line 254 and the string drain region 239. Additionally, an ohmic layer may be formed between the bit line contact 253 and the string drain region 239.

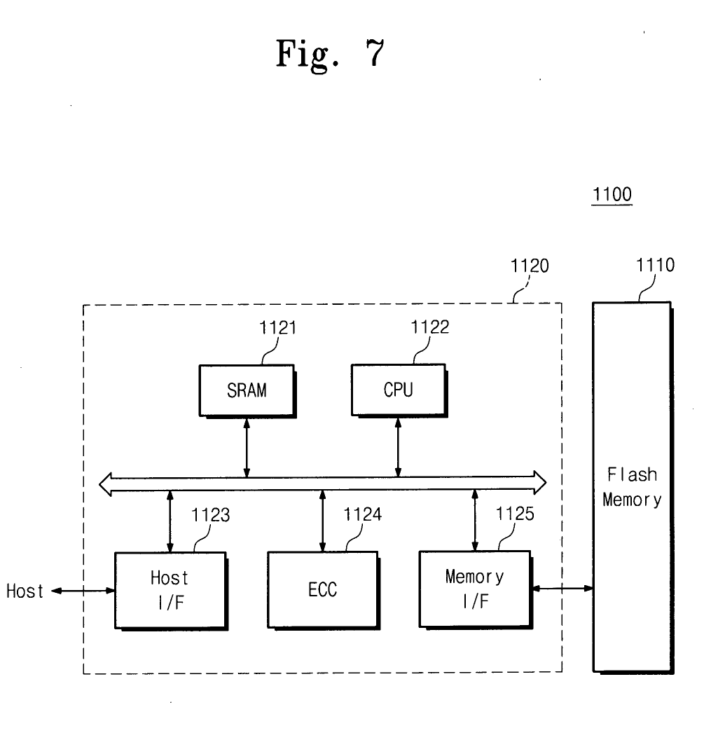

With reference to FIG. 7, a device applying the semiconductor device according to the exemplary embodiments of the inventive concept will be described. FIG. 7 is a block diagram illustrating an example including the semiconductor device according to the exemplary embodiment of the inventive concept. In this example, the semiconductor device may be applicable to a flash memory 1110. The semiconductor device according to the embodiment of the inventive concept is mounted in a memory card 1100 to support data storage capability at a high capacity. The memory card 1100 may include a memory controller 1120 for controlling data exchange as a whole between a host and the flash memory 1110.

The memory controller 1120 may include a central processing unit 1122, an SRAM 1121, an error correction code 1124, a host interface 1123, and a memory interface 1125. The SRAM 1121 may be used as an operation memory of the central processing unit 1122. The host interface 1123 may have a data exchanging protocol of the host connected to the memory card 1100. The error correction code 1124 may detect and correct errors in the data read from the flash memory 1110. The memory interface 1125 may interface with the flash memory 1110. The central processing unit 1222 may execute various control operations for data exchange of the memory controller 1120. The memory card 1100 may provide a system having high reliability due to improved reliability of the flash memory 1110 according to the exemplary embodiment of the invention.

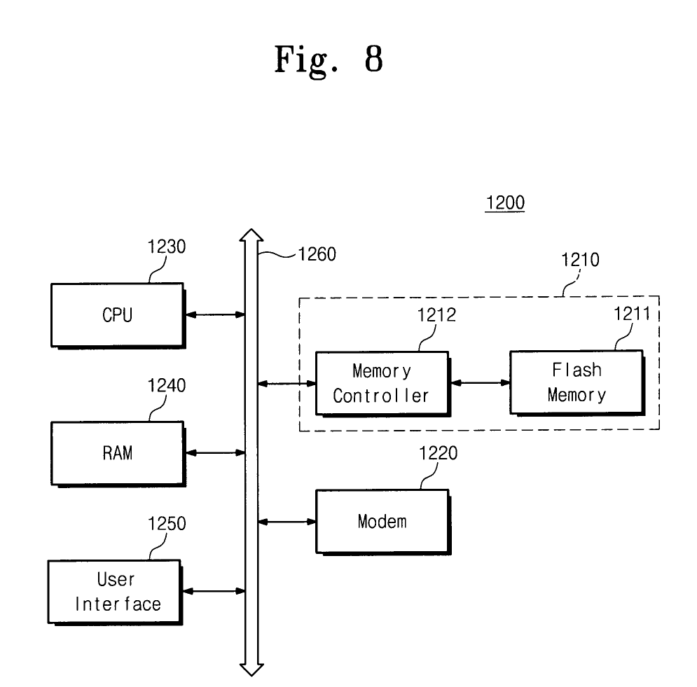

FIG. 8 illustrates another device applying the semiconductor device according to the exemplary embodiments of the inventive concept. FIG. 8 is a block diagram illustrating an information processing system 1200 including a memory system 1210. The memory system 1210 may include the semiconductor device according to the exemplary embodiments of the inventive concept. The memory system 1210 according to the embodiments of the inventive concept may be mounted in an information processing system such as mobile devices or desktop computers. The information processing system 1200 may include a memory system 1210, a modem 1220, a central processing unit 1230, a RAM 1240, and a user interface 1250, which are electrically connected to the memory system 1210 through a system bus 1260. The memory system 1210 may store data processed by the central processing unit 1230 or data input from the outside. In this applicable example, the memory system 1210 may be configured as a solid state disk (SSD). The memory system 1210 includes a memory controller 1212 and a flash memory 1211. In this embodiment, the information processing system 1200 may stably and reliably store a mass data in the memory system 1210. Moreover, the memory system 1210 can reduce resources required for the error correction, thereby providing a data exchanging function of high speed for the information processing system 1200.

In addition, the semiconductor device according to the embodiments of the inventive concept may be embodied in various types of packages. For example, the semiconductor device may be packaged and mounted in such manners as, for example, Package on Package (PoP), Ball Grid Arrays (BGAs), Chip Scale Packages (CSPs), Plastic Leaded Chip Carrier (PLCC), Plastic Dual In-Line Package (PDIP), Die in Waffle Pack, Die in Wafer Form, Chip On Board (COB), Ceramic Dual In-Line Package (CERDIP), Plastic Metric Quad Flat Pack (MQFP), Thin Quad Flatpack (TQFP), Small Outline (SOIC), Shrink Small Outline Package (SSOP), Thin Small Outline (TSOP), Thin Quad Flatpack (TQFP), System In Package (SIP), Multi Chip Package (MCP), Wafer-level Fabricated Package (WFP), Wafer-Level Processed Stack Package (WSP), and other such packages.

According to the exemplary embodiments of the inventive concept, the semiconductor device may include the source/drain regions doped with dopants in the active pattern. The cell string, which includes the source/drain regions doped with dopants, may more effectively execute writing and/or erasing operations. Furthermore, since the semiconductor device is not required to provide a separate circuit and/or additional voltage necessary for forming a reversal region in the active pattern, high integration is optimized.

The above-disclosed subject matter is to be considered illustrative and not restrictive, and the appended claims are intended to cover all such modifications, enhancements, and other embodiments, which fall within the true spirit and scope of the inventive concept. The inventive concept is to be determined by the broadest permissible interpretation of the following claims and their equivalents, and shall not be restricted or limited by the foregoing detailed description.

What is claimed is:

1. A semiconductor device comprising:
insulating patterns and gate patterns alternately stacked on a substrate;
an active pattern extending upward along sidewalls of the insulating patterns and the gate patterns on the substrate;
data storage patterns interposed between the gate patterns and the active pattern; and
a source/drain region disposed in the active pattern between a pair of gate patterns adjacent to each other.

2. The semiconductor device of claim 1, wherein a dopant concentration in the source/drain region is different from a dopant concentration in the active pattern.

3. The semiconductor device of claim 1, wherein the sidewalls of the insulating patterns define a undercut region by being recessed laterally relative to sidewalls of the gate patterns and a semiconductor pattern is disposed in the undercut region, and
wherein the source/drain region extends in the semiconductor pattern.

4. The semiconductor device of claim 3, wherein the data storage patterns extend to be interposed between the source/drain region in the undercut region and the gate pattern.

5. The semiconductor device of claim 4, wherein the data storage patterns include a tunnel barrier adjacent to the active pattern, a blocking insulating pattern adjacent to the gate pattern, and a charge storage pattern interposed between the tunnel barrier and the blocking insulating pattern.

6. The semiconductor device of claim 1, wherein a plurality of source/drain regions are disposed in the active pattern vertically spaced apart from one another.

7. The semiconductor device of claim 1, further comprising:
a base source region disposed between a lowermost gate pattern and the substrate; and
a string drain region disposed on an uppermost gate pattern.

8-10. (canceled)
